(19) United States
(12) Patent Application Publication
(10) Pub. No.: US 2016/0049962 A1
(43) Pub. Date: Feb. 18, 2016

(54) METHOD AND APPARATUS OF LDPC ENCODER IN 10GBASE-T SYSTEM

(71) Applicants: LI, Jian, (US); XUE, Yisheng, (US); HUANG, Yin, (US); XU, Changlong, San Diago, CA (US); HOU, Jilei, San Diago, CA (US); QUALCOMM INCORPORATED, San Diago, CA (US)

(72) Inventors: Jian Li, Beijing (CN); Ylsheng Xue, Beijing (CN); Yin Huang, Beijing (CN); Changlong Xu, Beijing (CN); Jilei Hou, Beijing (CN)

(21) Appl. No.: 14/779,708

(22) PCT Filed: Apr. 25, 2013
(86) PCT No.: PCT/CN2013/074713

§ 371 Date: Sep. 24, 2015

(51) Int. Cl. H03M 13/11; H03M 13/00

(52) U.S. Cl. CPC H03M 13/1174; H03M 13/616

(57) ABSTRACT

A method of data encoding is disclosed. A communications device receives a set of information bits to be encoded into a codeword (c), which includes the set of information bits and a set of parity bits. A first bit value is assigned to a first parity bit in the set of parity bits. The remaining parity bits are then encoded based, at least in part, on the first bit value assigned to the first parity bit. The device may encode the remaining parity bits using the set of information bits and a parity check matrix (H) for a low density parity check (LDPC) code. The device may also generate a new parity check matrix (H₀) based on linearly independent rows of the parity check matrix H, and iteratively evaluate each of the remaining parity bits based on the equation: H₀c=0. The device may then determine whether the encoded codeword c is a valid codeword given the LDPC code, and change one or more bit values of the codeword if c is not a valid codeword.

### TECHNICAL FIELD

The present embodiments relate generally to error detection in data communications, and specifically to error detection and/or correction based on low density parity check (LDPC) encoding.

### BACKGROUND OF RELATED ART

Many communications systems use error-correcting codes. Specifically, error correcting codes may compensate for the intrinsic unreliability of information transfer in these systems by introducing redundancy into the data stream. Low density parity check (LDPC) codes are a particular type of error correcting codes which use an iterative coding system. LDPC codes can be represented by bipartite graphs (often referred to as “Tanner graphs”), wherein a set of variable nodes corresponds to theinformation bits of a codeword, and a set of check nodes represents the parity-check constraints that define the code. A variable node and a check node are considered “neighbors” if they are connected by an edge in the graph. A bit sequence having a one-to-one association with the variable node sequence is a valid codeword if and only if, for each check node, the bits associated with all neighboring variable nodes sum to zero modulo two (i.e., they include an even number of 1's).

For example, FIG. 1A shows a bipartite graph 100 representing an exemplary LDPC code. The bipartite graph 100 includes a set of 5 variable nodes 110 (represented by circles) connected to 4 check nodes 120 (represented by squares). Edges in the graph 100 connect the variable nodes 110 to the check nodes 120. FIG. 1B shows a matrix representation 150 of the bipartite graph 100. The matrix representation 150 includes a parity check matrix H and a codeword vector x, where x₁-x₅ represent bits of the codeword x. More specifically, the codeword vector x represents a valid codeword if and only if Hx=0.

A received LDPC codeword can be decoded to produce a reconstructed version of the original codeword. In the absence of errors, or in the case of correctable errors, decoding can be used to recover the original data unit that was encoded. For example, an LDPC decoder may operate by exchanging messages within the bipartite graph 100, along the edges, and updating these messages by performing computations at the nodes based on the incoming messages. Each variable node 110 in the graph 100 may initially be provided with a “soft bit” (e.g., representing the received bit of the codeword) that indicates an estimate of the associated bit's value as determined by observations from the communications channel. The LDPC decoders may update the soft bits by iteratively reading them from, and writing them back to, memory based on the parity check constraints of the corresponding LDPC code.

The parity check matrix H used for decoding an LDPC codeword is “sparse” (i.e., the matrix H contains significantly fewer 1's than 0's). For example, the LDPC code adopted by the IEEE 802.3an Ethernet standard is a 384×2048 matrix with a row weight of 32 and a column weight of 6. In other words, each row of H has thirty-two 1's and each column of H has six 1's. The sparseness of H enables efficient decoding of received codewords. In contrast, a generator matrix (G) typically used for encoding LDPC codewords is not sparse (e.g., GH^{T}=0). Thus, due to such high encoding complexity, LDPC encoders that implement the generator matrix G are often very complicated and/or inefficient.

### SUMMARY

This Summary is provided to introduce in a simplified form a selection of concepts that are further described below in the Detailed Description. This Summary is not intended to identify key features or essential features of the claimed subject matter, nor is it intended to limit the scope of the claimed subject matter.

A device and method of operation are disclosed that may aid in the encoding of data to be transmitted to another device. For some embodiments, the device may include a memory element to store a set of information to be encoded into a codeword (c), wherein the codeword includes the set of information bits and a set of parity bits; and one or more processors to (i) assign a first bit value to a first parity bit in the set of parity bits, and (ii) encode the remaining parity bits in the set of parity bits based, at least in part, on the first bit value assigned to the first parity bit. The one or more processors may encode the remaining parity bits using the set of information bits and a parity check matrix (H) for a low density parity check (LDPC) code. The one or more processors may also determine whether the encoded codeword is a valid codeword given the LDPC code, and may change one or more bit values of the codeword if it is not a valid codeword.

For some embodiments, a new parity check matrix (H₀) may be generated based on linearly independent rows of the parity check matrix H.Each of the remaining parity bits may then be iteratively evaluated based on the equation: H₀c=0. Specifically, the remaining parity bits may be evaluated by iteratively solvingone or more vector equations.

For some embodiments, the first parity bit may be assigned a second bit value if the codeword is not a valid codeword. The one or more processors may then determine which, if any, of the remaining parity bits are affected by the first parity bit and change the bit values of the affected parity bits. For example, the one or more processors may look up the affected parity bits in a lookup table.

Encoding LDPC codewords using the parity check matrix H (e.g., rather than the generator matrix G) substantially reduces the complexity of encoding operations due to the sparseness of H. Moreover, assuming a bit value for the first parity bit, and iteratively evaluating the remaining parity bits based on that assumption, enables the LDPC encoding operations to be performed quickly, in a substantially linear manner. Furthermore, because only a finite number of the remaining parity bits may be affected by an incorrect assumption for the value of the first parity bit, a codeword that is generated based on an incorrect assumption may be subsequently corrected in a single step (e.g., by changing the bit values of the affected parity bits).

### BRIEF DESCRIPTION OF THE DRAWINGS

The present embodiments are illustrated by way of example and are not intended to be limited by the figures of the accompanying drawings, where:

FIGS. 1A-1B show graphical and matrix representations of an exemplary LDPC code;

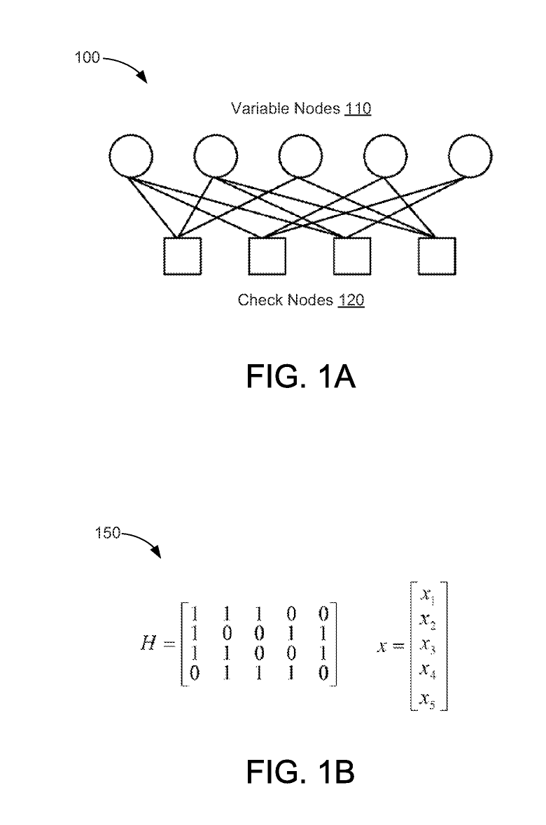

FIG. 2 shows a communications system in accordance with some embodiments;

FIG. 3 is an illustrative flow chart depicting a data encoding operation in accordance with some embodiments;

FIG. 4 is a block diagram of an LDPC processing device in accordance with some embodiments;

FIG. 5 is an illustrative flow chart depicting a method of evaluating the parity bits of a codeword in accordance with some embodiments;

FIG. 6 is an illustrative flow chart depicting another data encoding operation, in accordance with some embodiments; and

FIG. 7 is a block diagram of an encoder in accordance with some embodiments.

### DETAILED DESCRIPTION

In the following description, numerous specific details are set forth such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present embodiments. However, it will be apparent to one skilled in the art that these specific details may not be required to practice the present embodiments. In other instances, well-known circuits and devices are shown in block diagram form to avoid obscuring the present disclosure. Any of the signals provided over various buses described herein may be time-multiplexed with other signals and provided over one or more common buses. Additionally, the interconnection between circuit elements or software blocks may be shown as buses or as single signal lines. Each of the buses may alternatively be a single signal line, and each of the single signal lines may alternatively be buses, and a single line or bus might represent any one or more of a myriad of physical or logical mechanisms for communication between components. The present embodiments are not to be construed as limited to specific examples described herein but rather to include within their scope all embodiments defined by the appended claims.

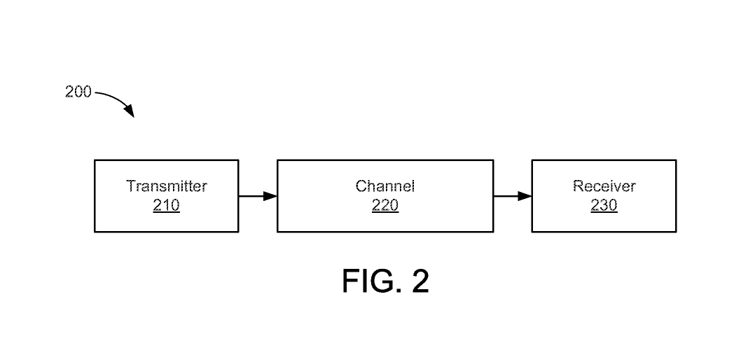

FIG. 2 shows a communications system 200 in accordance with some embodiments. A transmitter 210 transmits a signal onto a channel 220, and a receiver 230 receives the signal from the channel 220. The transmitter 210 and receiver 230 may be, for example, computers, switches, routers, hubs, gateways, and/or similar devices. For some embodiments, the communications system is a 10GBASE-T Ethernet system based on the IEEE 802.3an Ethernet standard (e.g., the channel 220 is a wired link), although other wired communication standards may be employed by system 200. In other embodiments, the channel 220 may be wireless.

Imperfections of various components in the communications system 200 may become sources of signal impairment, and thus cause signal degradation. For example, imperfections in the channel 220 may introduce channel distortion, which may include linear distortion, multi-path effects, and/or Additive White Gaussian Noise (AWGN). To combat potential signal degradation, the transmitter 210 and the receiver 230 may include LDPC encoders and decoders, respectively. Specifically, the transmitter 210 may perform LDPC encoding on outgoing data to produce a codeword that can be subsequently decoded by the receiver 230 (e.g., through an LDPC decoding operation) to recover the original data. For some embodiments, the transmitter 210 may generate codewordsbased on a parity check matrix (H) associated with an LDPC code used by both the transmitter 210 and the receiver 230. Further, for some embodiments, the transmitter 210 may generate a set of parity bits for the codeword by assuming an initial bit value for a first parity bit and iteratively evaluating the remaining parity bits based on the initial bit value of the first parity bit.

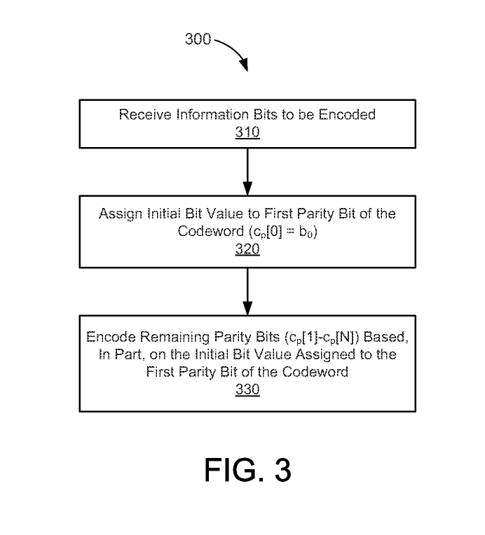

FIG. 3 is an illustrative flow chart depicting a data encoding operation 300 in accordance with some embodiments. With reference, for example, to FIG. 2, the transmitter 210 first receives a set of information bits to be encoded and transmitted (310). For some embodiments, the information bits may be encoded into LDPC codewords (c) based on an LDPC code that is shared between the transmitter 210 and the receiver 230. Each codeword c may include the original information bits (cₛ) as well as a set of parity bits (cₚ), which may be used to perform parity checks on and/or recover the original information bits cₛ. For some embodiments, the LDPC code may correspond to a (2048, 1723) regular LDPC code based on the 802.3an Ethernet standard (e.g., 10GBASE-T). Specifically, under the 802.3an Ethernet standard, 1723 information bits are combined with 325 parity bits to form a 2048-bit codeword.

The transmitter 210 then assigns an initial bit value (b₀) to a first parity bit (cₚ[0]) of the codeword c (320). As will be described in greater detail below, the initial bit value b₀ is an “assumption” for the actual bit value of the first parity bit cₚ[0]. Thus, for some embodiments, the initial bit value bₒmay be an arbitrary value (e.g., either 0 or 1) which may be changed or corrected if the assumption is subsequently determined to be incorrect. It should be noted that, in the present embodiments, an assumption is made with respect to the “first” parity bit (i.e., cₚ[0]) for simplicity only. For other embodiments, the initial bit value b₀ may be assumed for any of the parity bits cₚ[0]-cₚ[n].

Finally, the transmitter 210 encodes the remaining parity bits (cₚ[1]-cₚ[n]) based, in part, on the initial bit value b₀ assigned to the first parity bit cₚ[0] (330). For some embodiments, the remaining parity bits cₚ[1]-cₚ[n] may be evaluated based on the parity check matrix H, for example, by solving: Hc=0 (mod 2). Further, for some embodiments, the transmitter 210 may verify whether the parity bits cₚ[0]-cₚ[n]were properly encoded, for example, by determining whether the final codeword c is a valid codeword for the given LDPC code. If the codeword c does not represent a valid LDPC codeword, the transmitter 210 may “flip” or change the bit values of the first parity bit cₚ[0] and any remaining parity bits cₚ[1]-cₚ[n] that may have been incorrectly encoded based on the initial bit value b₀.

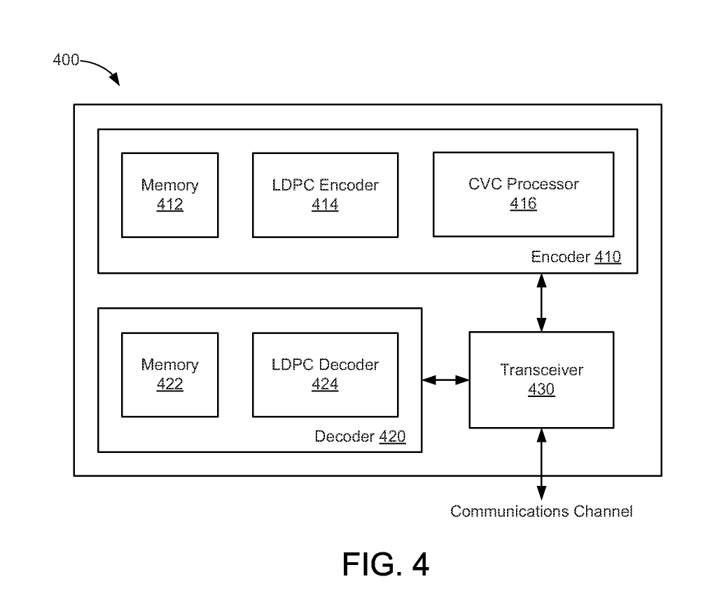

FIG. 4 is a block diagram of an LDPC processing device 400 in accordance with some embodiments. The LDPC processing device 400 includes an encoder 410, a decoder 420, and a transceiver 430 that transmits and/or receives LDPC-encoded codewords via a communications channel (e.g., channel 220 of FIG. 2). For some embodiments, the communications channel may correspond to a 10GBASE-T Ethernet channel (although other communication mediums may be used). For some embodiments, the LDPC code may be a regular (2048, 1723) LDPC code based on the 802.3an Ethernet standard (e.g., 10GBASE-T). Accordingly, each LDPC codeword may be 2048 bits in length,which includes 1723 information bits and 325 parity bits.

The encoder 410 includes a memory 412, an LDPC encoder 414, and a codeword verification and correction (CVC) processor 416. Specifically, the memory 412 may store information bits to be encoded by the LDPC encoder 414. The LDPC encoder 414 processes the information bits stored in the memory 412 by generating codewords c, based on an LDPC code, to be transmitted to another device. For some embodiments, the LDPC encoder 414 may generate the codewordsc based on a parity check matrix H associated with the LDPC code, for example, by assuming an initial bit value b₀ for the first parity bit cₚ[0] and evaluating the remaining parity bits cₚ[1]-cₚ[n] based on the equation: Hc=0. The CVC processor 416 determines whether the codewords c generated by the LDPC encoder 414 represent valid codewords given the LDPC code. For some embodiments, the CVC processor 416 may determine the validity of a codeword c by verifying that Hc=0. If c is not a valid codeword, the CVC processor 416 may modify the codeword c by flipping the bit values of the first parity bit cₚ[0] and any remaining parity bits cₚ[1]-cₚ[n] that are affected by the bit value of the first parity bit cₚ[0].

The decoder 420 includes a memory 422 and an LDPC decoder 424. The memory 422 may store codewords, received via the transceiver 430, to be decoded by the LDPC decoder 424. The LDPC decoder 424 processes the codewords stored in the memory 422 by performing parity check operations based on an LDPC code (note that the LDPC decoder 424 may perform the parity check operations using the same parity check matrix H that is used by the LDPC encoder 414 for generating codewords c). More specifically, the LDPC decoder 424 may verify the validity of the bits in the received codewords and/or attempt to correct, through the parity check operations, any bits that may have been received in error. For example, each parity check operation may involve reading a corresponding soft bit value from memory 422, combining the soft bit value with other soft bit values associated with a particular check node (e.g., a parity check constraint), and writing a bit value back to memory 422 that results from the check node operation. For some embodiments, the LDPC decoder 424 may include a plurality of processing elements to perform the parity check operations in parallel.If the LDPC decoder 424 is unable to correct one or more bit errors in a received codeword (thus resulting in a decoding error), then the decoder 424 may produce a decoding error message.

By using the parity check matrix H, instead of the generator matrix G, the encoder 410 may generate LDPC codewords by performing encoding operations with relatively low complexity (e.g., due to the sparseness of H). Moreover, assuming a bit value for the first parity bit cₚ[0], and iteratively evaluating the remaining parity bits cₚ[1]-cₚ[n] based on the assumption, enables the encoder 410 to generate codewords in a fast and substantially linear manner.

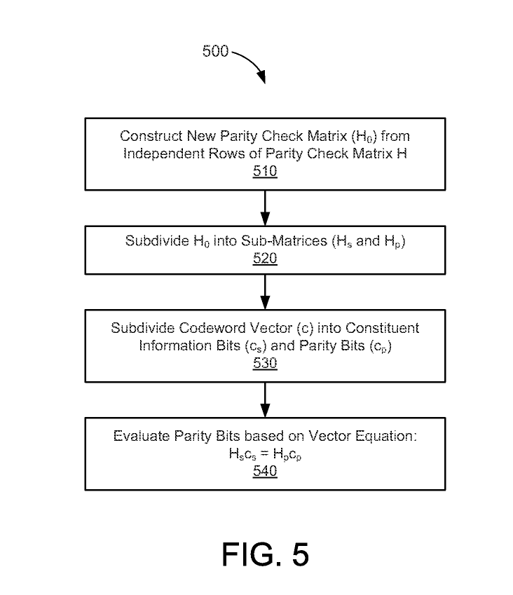

FIG. 5 is an illustrative flow chart depicting a method 500 of evaluating the parity bits of a codeword in accordance with some embodiments. A new parity check matrix H₀ is constructed from the linearly independent rows of the parity check matrix H (510). For example, the parity check matrix H for the 802.3an Ethernet standard LDPC code is a 384×2048 matrix with rank 325. Thus, of the 384 rows of H, only 325 are linearly independent (i.e., cannot be expressed as a linear combination of the other rows). Specifically, the 325 linearly independent rows are:
0,5,6,7,9,12,18,26,28,33,35,37,39,42,44,49,55,68,76,78,92,93,95,97,99,103,104,108, 110,112,115,127,129,140,143,145,155,157,158,160,175,176,177,184,187,191,197,198, 200,210,214,215,217,218,220,223,224,227,236,238,246,248,257,268,270,272,276, 281,284,287,288,292,293,294,305,315,319,324,325,329,339,344,347,360,380,382,13, 14,17,23,24,30,41,45,50,56,57,61,70,75,82,100,111,113,114,121,126,128,130,131,138, 144,147,148,149,152,153,179,181,182,189,192,194,196,199,204,211,219,231,234, 237,240,242,245,247,251,252,253,262,264,267,285,286,291,297,298,303,304,309,337, 346,365,20,25,34,46,74,139,161,166,188,195,201,202,216,235,239,261,269,275,300, 320,323,330,335,342,343,349,352,375,377,381,43,84,96,137,141,249,299,311,383, 38,164,302,348,208,301,73,83,162,359,90,254,280,378,58,150,183,186,250,21,27, 54,171,206,209,307,338,3,94,173,212,221,241,271,278,367,11,133,136,258,283,296, 328,337,358,373,15,31,106,125,225,232,310,314,322,336,376,60,81,117,119,124,169, 178,255,65,326,340,341,379,118,259,159,123,295,29,122,40,331,64,174,1,256,289, 362,51,86,101,142,228,230,266,2,72,120,135,163,317,321,345,354,355,59,62,66,67, 69,80,134,180,279,306,351,353,32,36,77,79,89,91,116,185,213,8,71,88,98,109,167,205, 226,105,107,371
   The resulting new parity check matrix H₀ for the 802.3an Ethernet standard LDPC code is a 325×2048 matrix that comprises the 325 independent rows (listed above) of the original parity check matrix H.

The new parity check matrix H₀ is then subdivided into two sub-matrices Hₛ and Hₚ (520). Specifically, an N×M parity check matrix H₀ may be expressed as:

H₀=[H_{S}H_{P}]

where Hₛ is an NxK sub-matrix (K corresponding to the number of information bits in each codeword) and Hₚ is an N×(M−K) sub-matrix (M−K corresponding to the number of parity bits in each codeword). As described above, the 802.3an Ethernet standard specifies a 2048-bit LDPC codewordcomprising 1723 information bits (i.e., K=1723) and 325 parity bits. Thus, the 325×2048 parity check matrix H₀ may be expressed in terms of a 325×1723 sub-matrix Hₛ and a 325×325 sub-matrix Hₚ.

Thecodewordc, expressed as a 1×M vector, is subdivided into constituent vectors cₛ and cₚ (530). More specifically, an M-bitcodeword c may be expressed as:

c=[c_{S}c_{P}]

where cₛ represents the K information bits to be encoded and cₚ represents the M−K parity bits. For example, with respect to the 802.3an Ethernet standard, a 2048-bit codeword c may be expressed in terms of the 1723 information bits cₛ and 325 parity bits cₚ.

Finally, the parity bits cₚ may be evaluated by solving the vector equation: Hₛcₛ=Hₚcₚ (540). For example, as described above, the parity check matrix H is defined such that Hc=0 for any valid codeword c. Because H₀ contains the independent rows of H, it follows that H₀c=0 for any valid codeword c. Substituting Hₛ and Hₚ for H₀, and cₛ and cₚ for c, produces the following equation:

H₀c=[H_{S}H_{P}Ic_{S}c_{P}]=H_{P}c_{P}+Hₛcₛ=0

In binary field encoding, the above equation can be rewritten as:

H_{P}c_{P}=Hₛcₛ=s

where s represents a solution vector obtained by multiplying the parity check sub-matrix Hₛ and the information bits cₛ. More specifically, because the information bits cₛ are known (i.e., they are the actual data bits to be encoded) and the elements of the sub-matrix Hₛ are also known (i.e., they correspond to the elements of the parity check matrix H), the product of Hₛcₛ can be represented by the solution vector s. Thus, the parity bits cₚ may be determined from the vector equation:

H_{P}c_{P}=s

It should be noted that cₚ may comprise a substantial number of unknown bit values (e.g., there are 325 parity bits for everycodeword under the 802.3an Ethernet standard). Thus, solving the above equation by brute force may involve a high level of encoding complexity. However, by first assuming a bit value for one of the parity bits, the remaining parity bits can be quickly determined in a substantially linear fashion.

By encoding LDPC codewords using the parity check matrix H, instead of the generator matrix G, the method 500 may substantially reduce the complexity of encoding operations due to the sparseness of H. The method 500 further reduces encoding complexity by using the new parity check matrix H₀, which contains only the linearly independent rows of the original parity check matrix H, for encoding.

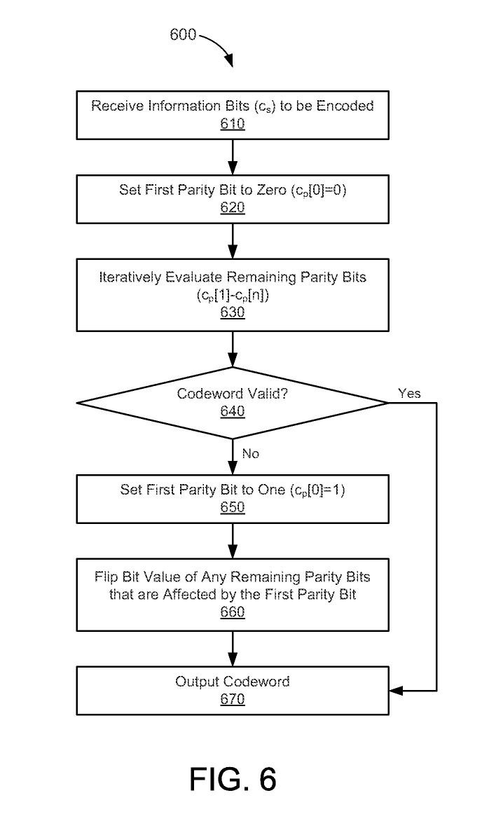

FIG. 6 is an illustrative flow chart depicting another data encoding operation 600, in accordance with some embodiments. As described above, the present embodiments may generate LDPC codewords c based on the parity check matrix H (or H₀) and by assuming an initial bit value for at least one of the parity bits cₚ. Referring also to FIG. 4, in the operation 600, the LDPC processing device 400 first receives a set of information bits cₛ to be encoded (610). For example, the information bits cₛ may be received from a central processing unit (CPU) of a communications device on which the LDPC processing device 400 also resides.

The LDPC processing device 400 generates LDPC codewords c by determining a set of parity bits cₚ for every set of information bits cₛ to be encoded (e.g., where c=[cₛcₚ]). As described above with reference to FIG. 5, the parity bits cₚ can be evaluated based on the equation: Hₚcₚ=Hₛcₛ=s. For some embodiments, the LDPC codewords c are generated by the encoder 410 of the LDPC processing device 400.

The LDPC encoder 414sets the first parity bit cₚ[0] of the codeword c to zero (620). As described above, the zero bit value assigned to the first parity bit cₚ[0] is an assumption for the actual bit value. For example, this assumption may allow the remaining parity bits cₚ[1]-cₚ[n] to be evaluated in a substantially linear fashion, with relatively low encoding complexity.

The LDPC encoder 414 then iteratively evaluates the remaining parity bits cₚ[1]-cₚ[n] based on the first parity bit cₚ[0] (630). In some embodiments, for each iteration, known parity bit values may be substituted into one or more vector equations (e.g., resulting from H₀c=0) involving, at most, one unknown parity bit. For example, during a first iteration, the first parity bit cₚ[0] may be substituted for its assumed value (e.g., cₚ[0]=0) in any vector equation(s) involving at most one additional unknown parity bit (e.g., cₚ[1]). As the only unknown parity bit in a particular vector equation, the value of cₚ[1]may be easily determined. In the next iteration, the two known parity bits cₚ[0] and cₚ[1]maybe substituted in one or more othervector equations involving at most one additional unknown parity bit (e.g., cₚ[2]). This process may be repeated until all of the remaining parity bits (e.g., cₚ[3]-cₚ[n]) have been evaluated.

After all of the parity bits cₚ[0]-cₚ[n] have been assigned a bit value, the CVC processor 416 checks the validity of the codeword c (640). For example, a valid codeword c should satisfy the equations: Hc=0 and/or H₀c=0. If the vector multiplication produces a 0, then c is valid codeword; if the vector multiplication produces a 1, then c is not a valid codeword. It should be noted that the CVC processor 416 need not evaluate every row-product of Hc (or H₀c) to determine whether c is a valid codeword. For some embodiments, the CVC processor 416 may verify the validity of the codeword c simply by multiplying the codeword c by a row of the parity check matrix H₀ that is known to produce a lwhenever the codeword c is invalid. For example, under the 802.3an Ethernet standard, the CVC processor 416 can verify the validity of codewords generated in this manner by multiplying the codeword c by the last row of the parity check matrix H₀ (e.g., row 325 of matrix H₀, which corresponds to row 371 of matrix H for the 802.3an standard LDPC code).

If the CVC processor 416 determines that c is a valid codeword (640), it proceeds by outputting the codeword c as the final “encoded” codeword (670). For example, the codeword c may be forwarded to the transceiver 430, which may then transmit the codeword c to another device in the network. However, if the CVC processor 416 determines that c is not a valid codeword (640), it is because the assumption for the first parity bit cₚ[0] was incorrect (e.g., cₚ[0]≠0).

Thus, if c is not a valid codeword (640), the CVC processor 416 may set the first parity bit cₚ[0] to one (650). Recall that cₚ[0] was initially assumed to be 0 (620), and the remaining parity bitscp[1]-cp[n] were evaluated based on that assumption. If the assumption regarding the first parity bit cₚ[0] is incorrect, then any remaining parity bitsthat were dependent upon that incorrect assumption will also have the wrong bit value as a result. Therefore, the CVC processor 416 may flip the bit values of any such remaining parity bits cₚ[1]-cₚ[n] that may have been affected by the initial bit value assigned to the first parity bit cₚ[0] (660). For some embodiments, the LDPC encoder 414 may re-evaluate the other parity bits cₚ[1]-cₚ[n] based on the new bit value assigned to the first parity bit cₚ[0] (660).

Note that not all of the remaining parity bits cₚ[1]-cₚ[n] may be affected by the bit value assigned to cₚ[0]. In other words, some parity bits may be evaluated to the same bit value regardless of whether cₚ[0]=0 or 1. Furthermore, the affected parity bits depend only on the parity check matrix H₀ (or H), and may therefore be determined prior to the encoding. Thus, for some embodiments, after changing the bit value of the first parity bit cₚ[0] (650), the CVC processor 416 may simply flip the bit values of any affected parity bits among the remaining parity bits cₚ[1]-cₚ[n] (660).

For example, with reference to the 802.3an standard LDPC code, there are exactly 55 parity bits cₚ that depend on (or are affected by) the bit value of the first parity bit cₚ[0]. These 55 parity bits are:
97,106,181,188,197,198,201,204,207,215,225,228,229,231,232,235,237,240,243,246, 247,249,253,258,260,262,267,268,269,274,276,279,280,281,284,289,293,295,296,301, 303,304,306,307,309,310,311,312,313,314,31318,319,320,322
   In the above example, if c is not a valid codeword (e.g., under the assumption that cₚ[0]=0), the CVC processor 416 may set cₚ[0]=1 (650) and flip the bit values (e.g., by changing 0's to 1's, and vice-versa) of the remaining 55 parity bits listed above (660).

After the first parity bit cₚ[0] and any affected parity bits, among the remaining parity bits cₚ[1]-cₚ[n], have been flipped (650-660), the resulting codeword c will be a valid codeword. Thus, the CVC processor 416 may output this “corrected”codeword c as the final encoded codeword (670).

Assuming a bit value for the first parity bit cₚ[0], and iteratively evaluating the remaining parity bits cₚ[1]-cₚ[n] based on that assumption, enables the data encoding operation 600 to be performed in a fast and substantially linear manner. Because only a fixed set of parity bits are affected by the bit value of the first parity bit cₚ[0], and because the affected parity bits can be predetermined, a codeword c that is generated based on an incorrect assumption (e.g., cp[0]≠0) can be corrected in a single step (e.g., by flipping the affected parity bits).

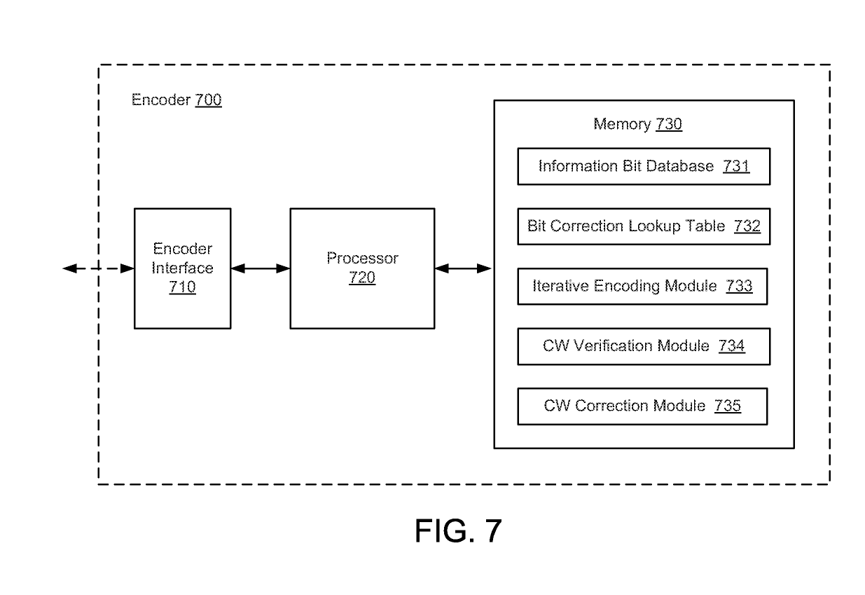

FIG. 7 is a block diagram of an encoder 700 in accordance with some embodiments. The encoder700 includes an encoder interface 710, a processor 720, and memory 730. The encoder interface 710 may be used for communicating data to and/or from the encoder 700. For example, the encoder interface 710 may receive information bits (e.g., from a CPU) to be encoded into one or more codewords. The encoder interface 710 may also output codewords generated by the encoder 700 (e.g., to a transceiver).

Memory 730 may include an information bit database 731 that may be used as a local cache to store received information bits, anda bit correction lookup table 732 that may be used to store information identifying one or more affected parity bits.As described above, the affected parity bits correspond with one or more parity bits cₚ of a codeword c which may be affected by the bit value of a first parity bit (e.g., cₚ[0]).

Furthermore, memory 730 may also include a non-transitory computer-readable storage medium (e.g., one or more nonvolatile memory elements, such as EPROM, EEPROM, Flash memory, a hard drive, etc.) that can store one or more of the following software modules:
aniterative encoding module 733 to generate LDPC codewords using a parity check matrix H associated with the LDPC code by assigning an initial bit value to a first parity bit of each codeword;
acodeword (CW) verification module 734 to verify whether each codeword generated by the iterative encoding module 733 represents a valid codeword for the given LDPC code; and
a CW correction module 735 to flip (i.e., change) one or more parity bits of a codewordthat is determined to be invalid.
   Each software modulemay include instructions that, when executed by the processor 720, may cause the encoder 700 to perform the corresponding function. Thus, the non-transitory computer-readable storage medium of memory 730 may include instructions for performing all or a portion of the operations described with respect to FIGS. 5-6.

The processor 720, which is coupled between the encoder interface 710 and the memory 730, may be any suitable processor capable of executing scripts of instructions of one or more software programs stored in the decoder 700 (e.g., within memory 730). For example, the processor 720 can execute the iterative encoding module 733, the CW verification module 734, and/or the CW correction module 735.

The iterative encoding module 733may be executed by the processor 720to process the information bits stored in the information bit database 731 by generating LDPC codewords c. For example, the iterative encoding module 733, as executed by the processor 720, may determine a set of parity bits cₚ for the codeword c based on the information bits cₛ to be encoded and a parity check matrix H associated with the LDPC code. For some embodiments, the processor 720 may generate a codeword c by assuming an initial bit value b₀ for a first parity bit cₚ[0] of the codeword c, and iteratively evaluating the remaining parity bits cₚ[1]-cₚ[n] based on the equation: Hₚcₚ=Hₛcₛ (e.g., as described above in reference to FIGS. 5-6).

The CW verification module 734 may be executed by the processor 720todetermine whether the codewords c generated by the iterative encoding module 733 represent valid codewords for the given LDPC code. For example, the CW verification module 734, as executed by the processor 720, may determine the validity of a codeword c by verifying that Hc=0. For some embodiments, the processor 720, in executing the CW verification module 734, may verify the validity of the codeword c by multiplying the codeword c by a single row of the parity check matrix H that is known to produce a 1 whenever the codeword c is invalid (e.g., as described above in reference to FIG. 5). If c is a valid codeword, the processor 720 may forward the codeword c to the encoder interface 710, for example, to be output to a transceiver. However, if c is not a valid codeword, the processor 720 may instead execute the CW correction module 735.

The CW correction module 735, as executed by the processor 720, may correct or modify a codeword c that is determined to be invalid by the CW verification module 734. For example, the processor 720, in executing the CW correction module 735, may flip the bit values for one or more parity bits cₚ[1]-cₚ[n] that are affected by the initial bit value assumed for the first parity bit cₚ[0]. For some embodiments, the processor 720 may correct the codeword c by flipping the value of the first parity bit cₚ[0] and subsequently re-evaluating the remaining parity bits cₚ[1]-cₚ[n]. For other embodiments, the processor 720 may correct the codeword c by looking up the affected parity bits in the bit correction lookup table 732, and flipping the bit values of only the affected parity bits (e.g., which includes the first parity bit cₚ[0] and any other parity bits cₚ[1]-cₚ[n] that are affected by the first parity bit cₚ[0]).

In the foregoing specification, the present embodiments have been described with reference to specific exemplary embodiments thereof. It will, however, be evident that various modifications and changes may be made thereto without departing from the broader scope of the disclosure as set forth in the appended claims. The specification and drawings are, accordingly, to be regarded in an illustrative sense rather than a restrictive sense. For example, the method steps depicted in the flow charts of FIGS. 3, 5 and 6 may be performed in other suitable orders, multiple steps may be combined into a single step, and/or some steps may be omitted.

What is claimed is:

1. A method of data encoding comprising:
receiving a set of information bits to be encoded into a codeword (c), wherein the codeword includes the set of information bits and a set of parity bits;
assigning a first bit value to a first parity bit in the set of parity bits; and
encoding remaining parity bits in the set of parity bits based, at least in part, on the first bit value assigned to the first parity bit, wherein encoding the remaining parity bits comprises:
determining whether the codeword is a valid codeword for a given LDPC code; and
changing one or more bit values of the codeword if the codeword is not a valid codeword.

2. The method of claim 1, wherein the remaining parity bits are encoded using the set of information bits and a parity check matrix (H) for a low density parity check (LDPC) code.

3. The method of claim 2, further comprising:
generating a new parity check matrix (H₀) using linearly independent rows of the parity check matrix.

4. The method of claim 3, wherein encoding the remaining parity bits comprises:
iteratively evaluating each of the remaining parity bits using the equation: H₀c=0.

5. The method of claim 4, wherein iteratively evaluating each of the remaining parity bits comprises:
for each iteration, solving one or more vector equations that include at most one unknown parity bit.

6. The method of claim 1, wherein changing one or more bit values of the codeword:
assigning a second bit value to the first parity bit, wherein the second bit value is different than the first bit value; and
changing one or more bit values of the remaining parity bits based, at least in part, on the second bit value.

7. The method of claim 6, wherein changing the one or more bit values of the remaining parity bits comprises:
changing a respective bit value of each of the one or more remaining parity bits that are affected by the first parity bit.

8. The method of claim 7, further comprising:
generating a first parity check matrix using linearly independent rows of a second parity check matrix that is associated with the given LDPC code, wherein identifying the one or more remaining parity bits that are affected by the first parity bit includes identifying the one or more remaining parity bits based, at least in part, on the first parity check matrix.

9. The method of claim 8, wherein identifying the one or more remaining parity bits that are affected by the first parity bit comprises:
looking up the one or more remaining parity bits in a lookup table.

10. (canceled)

11. A computer-readable storage medium containing program instructions that, when executed by a processor provided within a communications device, causes the device to:
receive a set of information bits to be encoded into a codeword (c), wherein the codeword includes the set of information bits and a set of parity bits;
assign a first bit value to a first parity bit in the set of parity bits; and
encode remaining parity bits in the set of parity bits based, at least in part, on the first bit value assigned to the first parity bit, wherein execution of the program instructions to encode the remaining parity bits causes the device to:
determine whether the codeword is a valid codeword for a given LDPC code; and
change one or more bit values of the codeword if the codeword is not a valid codeword.

12. The computer-readable storage medium of claim 10, wherein the remaining parity bits are encoded using the set of information bits and a parity check matrix (H) for a low density parity check (LDPC) code.

13. The computer-readable storage medium of claim 11, further comprising program instructions that cause the device to:
generate a new parity check matrix (H₀) using linearly independent rows of the parity check matrix.

14. The computer-readable storage medium of claim 12, wherein execution of the program instructions to encode the remaining parity bits causes the device to:
iteratively evaluate each of the remaining parity bits using the equation H₀c=0.

15. The computer-readable storage medium of claim 13, wherein execution of the program instructions to iteratively evaluate each of the remaining parity bits causes the device to:
for each iteration, solve one or more vector equations that include at most one unknown parity bit.

16. The computer-readable storage medium of claim 10, wherein execution of the program instructions to change the one or more bit values of the codeword causes the device to:
assign a second bit value to the first parity bit, wherein the second bit value is different than the first bit value; and
change one or more bit values of the remaining parity bits based, at least in part, on the second bit value.

17. The computer-readable storage medium of claim 15, wherein execution of the program instructions to change the one or more bit values of the remaining parity bits causes the device to:
identify one or more remaining parity bits that are affected by the first parity bit; and
change a respective bit value of each of the one or more remaining parity bits that are affected by the first parity bit.

18. The computer-readable storage medium of claim 16, further comprising program instructions that cause the device to:
generate a first parity check matrix using linearly independent rows of a second parity check matrix that is associated with the given LDPC code, wherein the program instructions to identify the one or more remaining parity bits include instructions for identifying the one or more remaining parity bits based, at least in part, on the first parity check matrix.

19. (canceled)

20. The computer-readable storage medium of claim 17, wherein execution of the program instructions to identify the one or more remaining parity bits that are affected by the first parity bit causes the device to:
look up the one or more remaining parity bits in a lookup table.

21. A communications device, comprising:
a memory element to store a set of information bits to be encoded into a codeword (c), wherein the codeword includes the set of information bits and a set of parity bits; and
one or more processors to:
assign a first bit value to a first parity bit in the set of parity bits; and
encode remaining parity bits in the set of parity bits based, at least in part, on the first bit value assigned to the first parity bit, wherein the one or more processors are to encode the remaining parity bits by:
determining whether the codeword is a valid codeword for a given LDPC code; and
changing one or more bit values of the codeword if the codeword is not a valid codeword.

22. The device of claim 19, wherein the remaining parity bits are encoded using the set of information bits and a parity check matrix (H) for a low density parity check (LDPC) code.

23. The device of claim 20, wherein the one or more processors are to further:
generate a new parity check matrix (H₀) using linearly independent rows of the parity check matrix.

24. The device of claim 21, wherein the one or more processors are to encode the remaining parity bits by:
iteratively evaluating each of the remaining parity bits using the equation: H₀c=0.

25. The device of claim 22, wherein the one or more processors are to iteratively evaluate each of the remaining parity bits by:
for each iteration, solving one or more vector equations that include at most one unknown parity bit.

26. The device of claim 19, wherein the one or more processors are to change the one or more bit values of the codeword by:
assigning a second bit value to the first parity bit, wherein the second bit value is different than the first bit value; and
changing one or more bit values of the remaining parity bits based, at least in part, on the second bit value.

27. The device of claim 24, wherein the one or more processors are to change the one or more bit values of the remaining parity bits by:
identifying one or more remaining parity bits that are affected by the first parity bit; and
changing a respective bit value of each of the one or more remaining parity bits that are affected by the first parity bit.

28. The device of claim 25, wherein the one or more processors are to further:
generate a first parity check matrix using linearly independent rows of a second parity check matrix that is associated with the given LDPC code; and
identify the one or more remaining parity bits that are affected by the first parity bit by identifying the one or more remaining parity bits based, at least in part, on the first parity check matrix.

29. The device of claim 26, wherein the one or more processors are to identify the one or more remaining parity bits that are affected by the first parity bit by:
looking up the one or more remaining parity bits in a lookup table.

30. (canceled)

31. The device of claim 19, wherein the device is part of a 10GBASE-T Ethernet system.

32. A communications device, comprising:
means for receiving a set of information bits to be encoded into a codeword (c), wherein the codeword includes the set of information bits and a set of parity bits;
means for assigning a first bit value to a first parity bit in the set of parity bits; and
means for encoding remaining parity bits in the set of parity bits based, at least in part, on the first bit value assigned to the first parity bit, wherein the means for encoding the remaining parity bits is to:
determine whether the codeword is a valid codeword for a given LDPC code; and
change one or more bit values of the codeword if the codeword is not a valid codeword.

33. The device of claim 29, wherein the remaining parity bits are encoded using the set of information bits and a parity check matrix (H) for a low density parity check (LDPC) code.

34. The device of claim 30, further comprising:
means for generating a new parity check matrix (H₀) using linearly independent rows of the parity check matrix H.

35. The device of claim 31, wherein the means for encoding the remaining parity bits is to:
iteratively evaluate each of the remaining parity bits using the equation: H₀c=0.

36. The device of claim 32, wherein the means for iteratively evaluating each of the remaining parity bits is to:
solve, for each iteration, one or more vector equations that include at most one unknown parity bit.

37. The device of claim 29, wherein the means for encoding the remaining parity bits is to further:
assign a second bit value to the first parity bit, wherein the second bit value is different that the first bit value; and
change one or more bit values of the remaining parity bits based, at least in part, on the second bit value.

38. The device of claim 34, wherein the means for encoding the remaining parity bits is to further:
identify one or more remaining parity bits that are affected by the first parity bit; and
change a respective bit value of each of the one or more remaining parity bits that are affected by the first parity bit.

39. The device of claim 35, wherein the means for encoding the remaining parity bits is to further:
identify one or more remaining parity bits that are affected by the first parity bit; and
change a respective bit value of each of the one or more remaining parity bits that are affected by the first parity bit.

40. (canceled)

41. The device of claim 29, wherein the device is part of a 10GBASE-T Ethernet system.
